(19) United States
(12) Patent Application Publication
(10) Pub. No.: US 2011/0174530 A1
(43) Pub. Date: Jul. 21, 2011

(54) Solder Ball Pin

(76) Inventor: Qing Man Suen, Zhejiang (CN)

(21) Appl. No.: 12/884,737

(22) Filed: Sep. 17, 2010

(30) Foreign Application Priority Data
Jan. 15, 2010 (CN) 201020049557.1

(51) Int. Cl. H05K 1/11

(52) U.S. Cl. 174/267

(57) ABSTRACT

A solder ball pin substantially includes a pillar pin body and an insulator whose opposite end facing a solder ball is formed by a soldering end. On the soldering end, a solderable metal layer is disposed concentrically with the insulator. A small opening whose dimension fits to a diameter of the pin body is defined on a center of the solderable metal layer. A reball end of the pin body penetrates the small opening on the solderable metal layer for fixing to the insulator body. The shape of the pin body could be alternatively formed by a terrace or shaped like a light beam without limitation of apertures with any varied diameters, which results in a flexible structure and the enhanced productivity. The solderable metal layer on the insulator allows the insulator to be solderable; a connection between the pin body and the insulator with the solderable metal layer becomes more compact, and the reliability of the soldering is promoted. Except the soldering part of the pin body, other non-soldered part of the pin body is wrapped in the insulator, which prevents the pin body from the oxidization and an inferior quality. Moreover, the assemblage of the insulator and the pin body does not readily deviate in view of any external force even after the soldering is processed. Thus, the assemblage is precise and controllable.

### BACKGROUND OF THE INVENTION

1. Field of the Invention

The present invention relates to a solder ball pin.

2. Description of the Related Art

Referring to FIGS. 1 and 2, several problems exist in the conventional solder ball pin as follows: 1. the structure of the ball pin is complicated, which results in a difficult processing and a high manufacturing cost; 2. the integral construction is so intricate that an elaborate fabrication is accordingly incurred, and the control over the accuracy is thence troublesome; 3. an interstice is facilely remained between a solderable metal layer and an insulator while the insulator is soldered; thus, any external force may easily cause a deviated insulator, which contributes to an inferior product; and 4. except the soldered part of the pin body, other non-soldered part of the pin body is exposed to the air, which adversely leads to the oxidization as well as a substandard manufactured goods.

### SUMMARY OF THE INVENTION

Therefore, the object of the present invention is to mend the defects contained in the existing solder ball pin by providing an improved solder ball pin whose structure is designed more practical and whose quality is superior.

The present invention mainly comprises a pin body, an insulator, and a solder ball. One end of the pin body is defined by a fixing end on a circuit board for being inserted into a hole on the circuit board. The other end of the pin body is defined by a reball end. The pin penetrates a through hole on a center of the insulator for fixing to the insulator. The fixing end on the circuit board and the reball end of the pin body are respectively exposed out of two sides of the insulator. Integrating the solder ball to the reball end of the pin body allows the solder ball to be fixed to the pin body as well as the insulator. The pin body adopts a pillar shape. A further end opposite to an end where the insulator is situated relative to the solder ball is designed by a soldering end. The soldering end has a solderable metal layer disposed concentrically with respect to the insulator. A center of the solderable metal layer defines a small opening whose dimension fits to a diameter of the pin body. The reball end of the pin body penetrating the small opening on the solderable metal layer allows the reball end fixing to the insulator.

Preferably, the pin body adopts a cylinder whose a diameter of an upper portion is larger than a diameter of a lower portion. A top of the upper portion is formed by the fixing end on the circuit board. A bottom of the lower portion is formed by the reball end. A terrace is formed on a convergence of the upper portion and the lower portion. The pin body and an upper face of the solderable metal layer contribute to a terrace-like limitation via the terrace.

As it should be, the shape of the pin body could alternatively adopt a terrace-like formation or a light-beam structure. The shape of the pin body of the present invention is not limited by any varied diameters of apertures. Thus, the present invention has a flexible assemblage and promotes the production efficiency. By means of the solderable metal layer on the insulator, the insulator becomes solderable, which allows the connection between the pin body and the insulator with the solderable metal layer to be more compact and dense. Therefore, a reliable soldering is achieved. Besides the soldered pin body, other non-soldered part of the pin body is wrapped in the insulator to avoid an oxidizing pin body. The assembled insulator and the pin body do not deviate easily in view of the external force after being soldered. Thus, the assemblage is accurate and controllable.

### BRIEF DESCRIPTION OF THE DRAWINGS

FIG. 1 is a schematic view showing a conventional solder ball pin;

FIG. 2 is a schematic view showing the conventional solder ball pin in using;

FIG. 3 is a schematic view showing a first preferred embodiment of the present invention;

FIG. 4 is a schematic view showing the first preferred embodiment of the present invention in using; and

FIG. 5 is a schematic view showing a second preferred embodiment of the present invention.

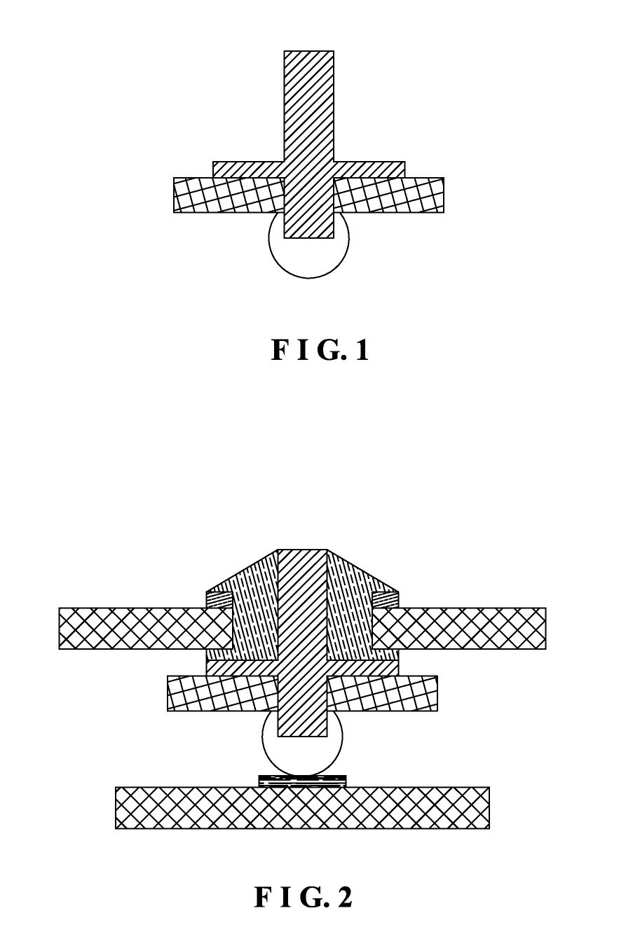

### DETAILED DESCRIPTION OF THE PREFERRED EMBODIMENTS

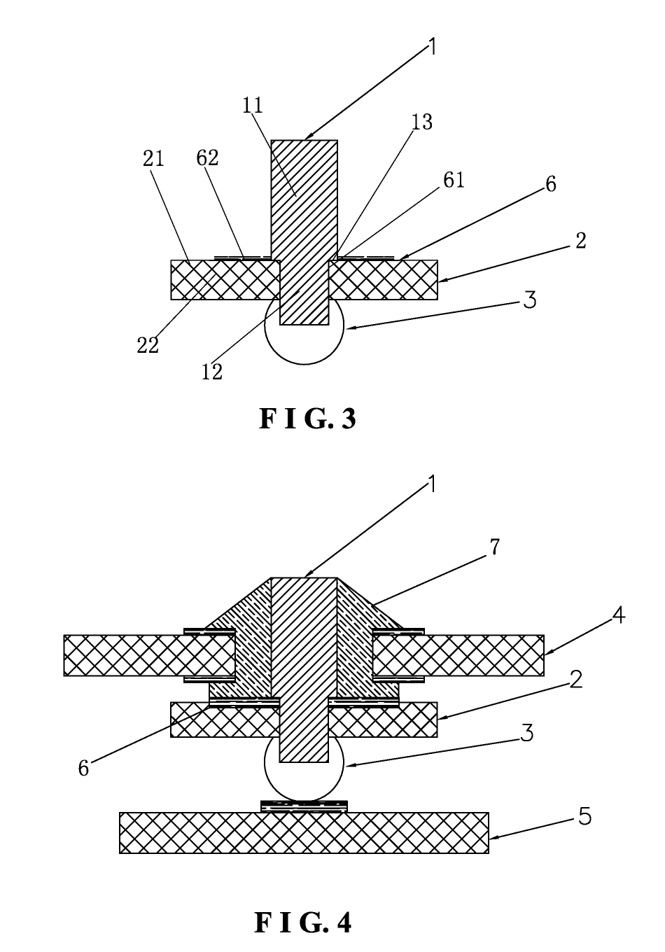

FIG. 3 shows a first preferred embodiment of the present invention. A solder ball pin substantially comprises a pin body 1, an insulator 2, a solder ball 3, and a solderable metal layer 6. The pin body 1 adopts a cylinder. A diameter of an upper portion 11 is larger than a diameter of a lower portion 12. A top of the upper portion 11 is formed by the fixing end on the circuit board. A bottom of the lower portion 12 is formed by a reball end. A terrace 13 is formed on a convergence of the upper portion 11 and the lower portion 12. The pin body 1 penetrates a through hole on a center of the insulator 2 for fixing to the insulator 2. The fixing end on the circuit board and the reball end of the pin body 1 are respectively exposed out of two sides of the insulator 2. A further end opposite to an end where the insulator 2 is situated relative to the solder ball 3 is designed by a soldering end 21. A depressed slot 22, defined on the soldering end 21 of the insulator 2, has the solderable metal layer 6 disposed concentrically with respect to the insulator 2. The height of the solderable metal layer 6 is larger than the depth of the depressed slot 22. A center of the solderable metal layer 6 defines a small opening 61 whose dimension fits to a diameter of the pin body 1. The reball end of the pin body 1 penetrating the small opening 61 on the solderable metal layer 6 allows the reball end to fix to the insulator 2 via the solder ball 3. Thereby, the pin body 1 and an upper face 62 of the solderable metal layer 6 contribute to a terrace-like limitation via the terrace 13.

FIG. 4 shows the present invention connected to an upper circuit board 4 and a lower circuit board 5. Herein, a solder 7 solders the circuit board 4 with the solderable metal layer 6 to result in a reliable connection.

The pin body 1 of afore embodiment is designed by the cylinder. The diameter of the upper portion 11 is larger than the diameter of the lower portion 12. Preferably, the dimension of the pin body 1 could be practically formed by either a larger upper portion cooperating with a smaller lower portion or a smaller upper portion cooperating with a larger lower portion.

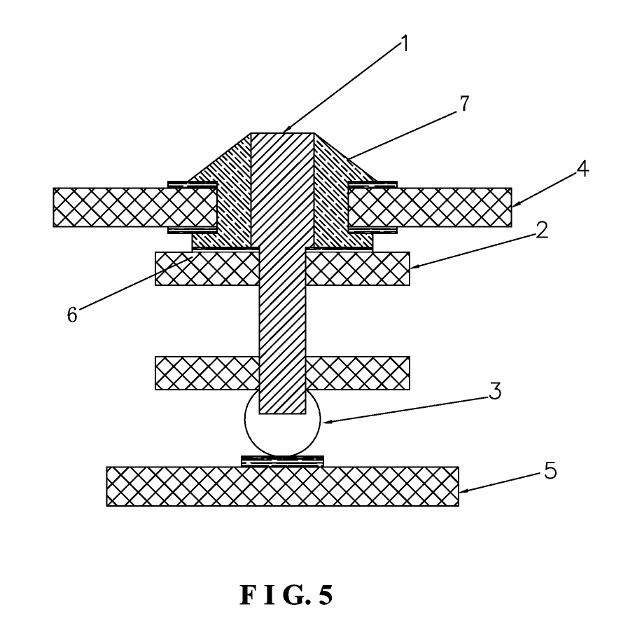

FIG. 5 shows a second preferred embodiment of the present invention. The lower portion 12 of the pin body 1 extends downward for installing two insulators 2.

I claim:

1. A solder ball pin comprising a pin body, an insulator, and a solder ball; one end of said pin body being defined by a fixing end on a circuit board for being inserted into a hole on said circuit board; the other end of said pin body being defined by a reball end; said pin body penetrating a through hole on a center of said insulator for fixing to said insulator; said fixing end on said circuit board and said reball end of said pin body being respectively exposed out of two sides of said insulator; integrating said solder ball to said reball end of said pin body allowing said solder ball to be fixed to said pin body as well as said insulator; characterized in that, said pin body adopts a pillar shape; a further end opposite to an end where said insulator is situated relative to said solder ball being designed by a soldering end; said soldering end having a solderable metal layer disposed concentrically with respect to said insulator; a center of said solderable metal layer defining a small opening whose dimension fits to a diameter of said pin body; said reball end of said pin body penetrating said small opening on said solderable metal layer allowing said reball end to fix to said insulator.

2. The solder pin ball as claimed in claim 1, wherein, said pin body adopts a cylinder, of which a diameter of an upper portion is larger than a diameter of a lower portion; a top of said upper portion is formed by said fixing end on said circuit board; a bottom of said lower portion is formed by said reball end; a terrace is formed on a convergence of said upper portion and said lower portion; said pin body and an upper face of said solderable metal layer contribute to a terrace-like limitation via said terrace.
